(19) United States
(12) Patent Application Publication
(10) Pub. No.: US 2020/0111539 A1
(43) Pub. Date: Apr. 9, 2020

(54) INFORMATION PROCESSING APPARATUS FOR REPAIR MANAGEMENT OF STORAGE MEDIUM

(71) Applicant: FUJITSU LIMITED, Kawasaki-shi (JP)

(72) Inventor: Hirobumi Yamaguchi, Kawasaki (JP)

(73) Assignee: FUJITSU LIMITED, Kawasaki-shi (JP)

(21) Appl. No.: 16/562,485

(22) Filed: Sep. 6, 2019

(30) Foreign Application Priority Data
Oct. 3, 2018 (JP) 2018-188260

(51) Int. Cl. G11C 29/44; G06F 11/10; G06F 11/07; G06F 11/30

(52) U.S. Cl. CPC G11C 29/4401; G06F 11/3062; G06F 11/0793; G06F 11/1048

(57) ABSTRACT

An information processing apparatus includes a memory, and a processor coupled to the memory and configured to acquire position information of regions of the memory where a correctable error occurs when detecting the correctable error over a predetermined number of times having a first value, specify, as software repair position information, position information having a frequency higher than the frequency of other position information among the acquired position information of regions, perform a software repair of a region indicated by the specified software repair position information, and confirm a presence or absence of an effect of the software repair of the region, and when the effect is determined to be present, set the software repair position information as hardware repair position information.

### CROSS-REFERENCE TO RELATED APPLICATION

This application is based upon and claims the benefit of the prior Japanese Patent Application No. 2018-188260 filed on Oct. 3, 2018, the entire contents of which are incorporated herein by reference.

### FIELD

The embodiments discussed herein are related to an information processing apparatus for a repair management of the storage medium.

### BACKGROUND

A dual inline memory module (DIMM) used for a main memory or the like of an information processing apparatus has a plurality of ranks, and each rank has a plurality of banks. FIG. 15 is a diagram illustrating the configuration of a DIMM. As illustrated in FIG. 15, a DIMM 100 has a plurality of ranks 110. The rank 110 has a plurality of banks 111.

FIG. 16 is a view illustrating a configuration of the bank 111. As illustrated in FIG. 16, the bank 111 has a plurality of rows and a plurality of columns, and constitutes a dynamic random access memory (DRAM) matrix. A region specified by a row position and a column position is a memory cell indicating 1-bit information. A memory cell in which an error has occurred is called a faulty cell, and a row including the faulty cell is called a faulty row.

Also, the bank 111 has a spare row, and the faulty row is switched to the spare row. One bank 111 has a plurality of spare rows. Repairing a fault row by switching the faulty row to the spare row is called a post package repair (PPR).

The PPR includes an hPPR and an sPPR. In the hPPR, a fuse switches a faulty row to a spare row. Therefore, the repair by the hPPR may not be undone. In the sPPR, software switches a faulty row to a spare row. Therefore, the repair by the sPPR is lost by reset.

A memory controller that controls reading of data from the DIMM and writing of data to the DIMM counts, in a rank unit, the number of correctable errors generated in the DIMM (e.g., an error correcting code (ECC) correctable error). The reason is that, for example, in the case of the ECC of a double-data-rate 4 (DDR4) DRAM, the ECC is added to the data bus of a rank (64 bits). Further, since there are many rows (e.g., 4096 or more), it is not practical to provide a counting counter for each row in the memory controller.

When the counted number of correctable errors reaches a preset threshold, the memory controller generates a system management interrupt (SMI) in a central processing unit (CPU) and stores the row position information of the last occurrence of a correctable error in a rank unit.

An SMI handler of the BIOS reads, from the memory controller, the row position information of the last occurrence of a correctable error, and transmits the read row position information to a baseboard management controller (BMC). The BMC is a device that is incorporated in the information processing apparatus and manages the information processing apparatus. The BMC receives and stores the row position information in a rank unit. The basic input/output system (BIOS) acquires the row position information from the BMC in a rank unit at startup, and switches the row indicated by the row position information to a spare row by the hPPR or the sPPR.

Further, there is a technique in which an error that has occurred once in a memory cell is regarded as a software error, and when an error occurs again, the error is regarded as a latent error and repaired using an on-chip redundancy.

There is also a memory failure analysis apparatus capable of performing a failure analysis of a memory under test simply, easily, and accurately. When the number of defective cells in any column line exceeds a reference number, the apparatus regards all memory cells in the line as defective cells, and detects line fail information indicating whether the number of defective cells in each row line and the number of defective cells within the row line exceed a predetermined reference number. When the number of defective cells in any row line exceeds the reference number, the apparatus regards all memory cells in the line as defective cells, and detects line fail information indicating whether the number of defective cells in each column line and the number of defective cells within the column line exceed a predetermined reference number. Therefore, since the apparatus is configured to detect defective cells except for the memory cells in the line determined to be line-failed, it is possible to simply, easily, and accurately determine whether the memory cell is line-failed.

Related techniques are disclosed in, for example, Japanese Laid-Open Patent Publication Nos. 2011-054263 and 11-102598.

### SUMMARY

According to an aspect of the embodiments, an information processing apparatus includes a memory, and a processor coupled to the memory and configured to acquire position information of regions of the memory where a correctable error occurs when detecting the correctable error over a predetermined number of times having a first value, specify, as software repair position information, position information having a frequency higher than the frequency of other position information among the acquired position information of regions, perform a software repair of a region indicated by the specified software repair position information, and confirm a presence or absence of an effect of the software repair of the region, and when the effect is determined to be present, set the software repair position information as hardware repair position information.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating the configuration of an information processing apparatus according to an embodiment;

FIG. 2 is a diagram illustrating an example of a CE counter;

FIG. 3 is a diagram illustrating an example of a CE threshold register;

FIG. 4 is a diagram illustrating an example of a final CE position register;

FIG. 5 is a diagram illustrating an example of a register that stores consumed energy by a DIMM;

FIG. 6 is a diagram illustrating an example of a register that stores the temperature of the DIMM;

FIG. 7A is a diagram illustrating an example of a register that specifies a position at which an access status is monitored;

FIG. 7B is a diagram illustrating an example of a counter register that integrates the number of accesses;

FIG. 8 is a diagram illustrating an example of sPPR position information;

FIG. 9 is a diagram illustrating an example of an sPPR position history entry;

FIG. 10 is a diagram illustrating an example of hPPR position information;

FIG. 11A is a first flowchart illustrating a flow of a PPR process by the information processing apparatus;

FIG. 11B is a second flowchart illustrating the flow of a PPR process by the information processing apparatus;

FIG. 11C is a third flowchart illustrating the flow of a PPR process by the information processing apparatus;

FIG. 12A is a first flowchart illustrating a flow of an information collection phase process;

FIG. 12B is a second flowchart illustrating the flow of an information collection phase process;

FIG. 13A is a first flowchart illustrating a flow of an effect confirmation phase process;

FIG. 13B is a second flowchart illustrating the flow of an effect confirmation phase process;

FIG. 14 is a diagram illustrating an example of a hardware configuration of a BMC;

FIG. 15 is a diagram illustrating the configuration of the DIMM;

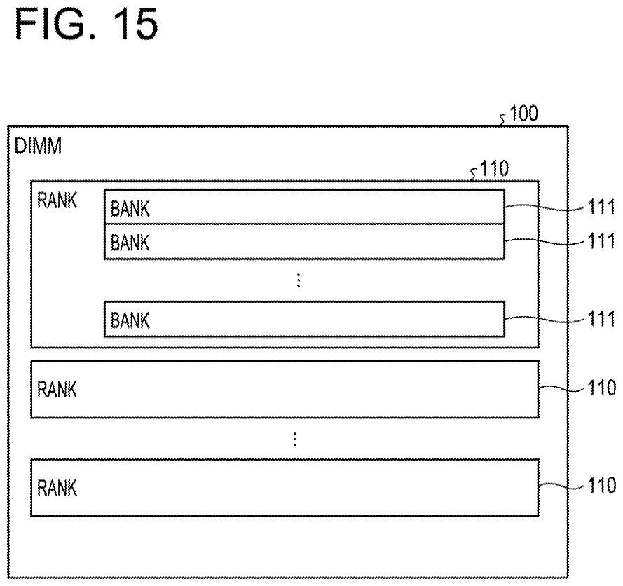

FIG. 16 is a diagram illustrating the configuration of a bank; and

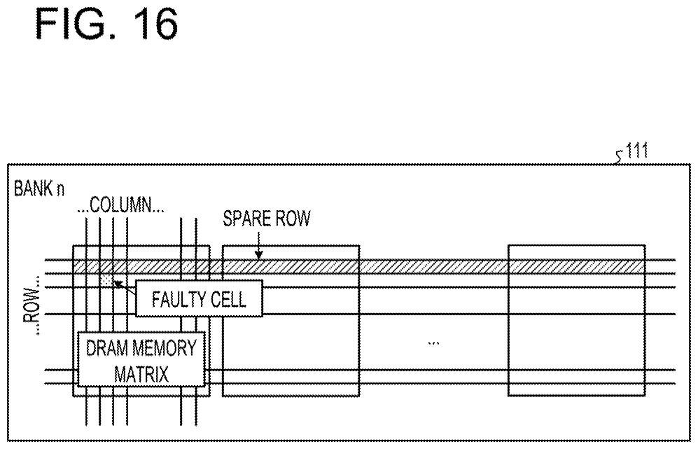

FIG. 17 is a diagram for explaining an example in which, in addition to the row of a correctable error that has occurred last, the rows in which more correctable errors have occurred are in the same rank.

### DESCRIPTION OF EMBODIMENTS

Since the BIOS may obtain only the row position information of the correctable error that has occurred last in a rank unit from the BMC at the time of startup, there is a problem that an inappropriate row may be subject to the PPR. For example, in addition to the row of the correctable error that has occurred last, the rows in which more correctable errors have occurred may be in the same rank.

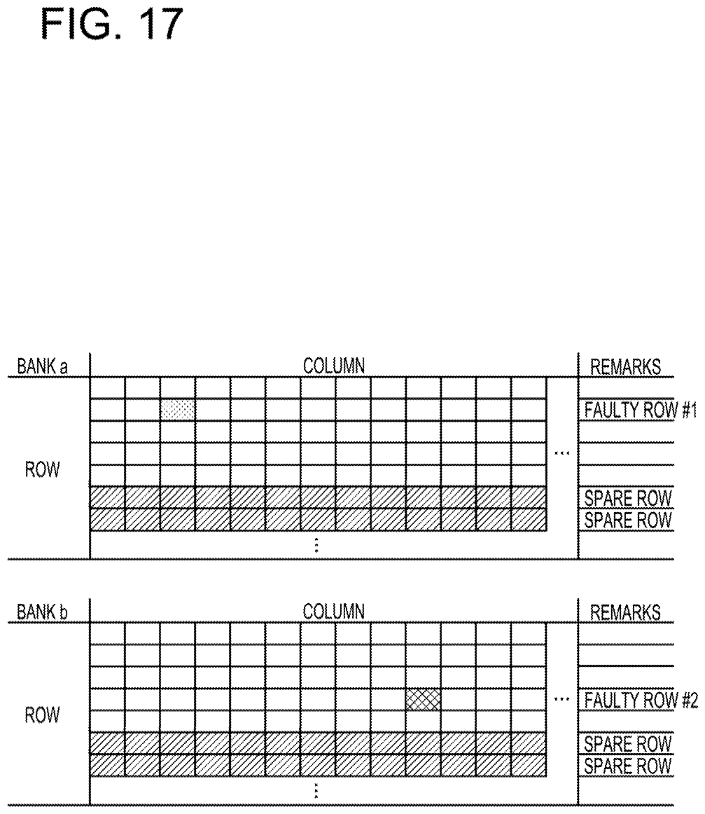

FIG. 17 is a diagram for describing an example in which, in addition to the row of the correctable error that has occurred last, the rows in which more correctable errors have occurred are in the same rank. In FIG. 17, it is assumed that bank a and bank b are in the same rank, a correctable error normally occurs in faulty row #1 of the bank a, and in faulty row #2 of the bank b, a correctable error occurs at an extremely low frequency as compared with the faulty row #1. Since the memory controller detects the correctable error for each rank, when the row of the correctable error that has occurred last is the faulty row #2, the position information stored by the memory controller becomes the position information of the faulty row #2, and the BIOS applies the PPR to the faulty row #2. However, in this case, the BIOS needs to preferentially apply the PPR to the faulty row #1 where the frequency of correctable errors is higher.

Hereinafter, detailed descriptions will be made on an embodiment of a technique of properly repairing a row in which a correctable error occurs in a memory module. Further, this embodiment does not limit the disclosed technology.

### EMBODIMENTS

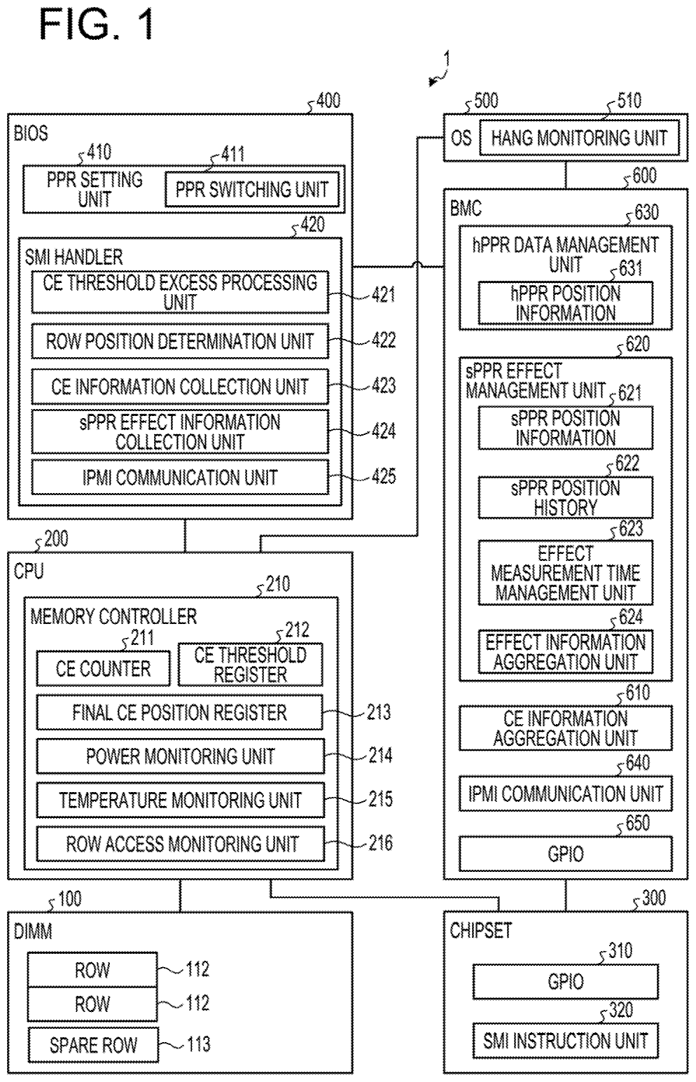

First, the configuration of the information processing apparatus according to an embodiment will be described. FIG. 1 is a diagram illustrating the configuration of an information processing apparatus according to the embodiment. As illustrated in FIG. 1, the information processing apparatus 1 according to the embodiment includes a DIMM 100, a CPU 200, a chipset 300, a BIOS 400, an operating system (OS) 500, and a BMC 600.

The DIMM 100 is a main memory of the information processing apparatus 1. The DIMM 100 stores a program executed by the information processing apparatus 1 and an intermediate result of execution of the program. The DIMM 100 has a plurality of rows 112 and a plurality of spare rows 113. The row 112 is switched to the spare row 113 by the PPR upon failure.

The CPU 200 is a central processing unit that reads a program from the DIMM 100 and executes the program. Although only one CPU 200 is illustrated in FIG. 1, a plurality of CPUs 200 may be provided. The CPU 200 includes a memory controller 210 that controls access to the DIMM 100.

The memory controller 210 has a plurality of memory channels. A plurality of DIMMs 100 are connected to each memory channel, but it is here assumed that one DIMM 100 is connected to one memory channel. The memory controller 210 and the DIMM 100 are connected by an SM bus, and the memory controller 210 may acquire information on a serial presence detect (SPD) and a thermal sensor on DIMM (TSOD) of the DIMM 100.

The memory controller 210 includes a CE counter 211, a CE threshold register 212, a final CE position register 213, a power monitoring unit 214, a temperature monitoring unit 215, and a row access monitoring unit 216.

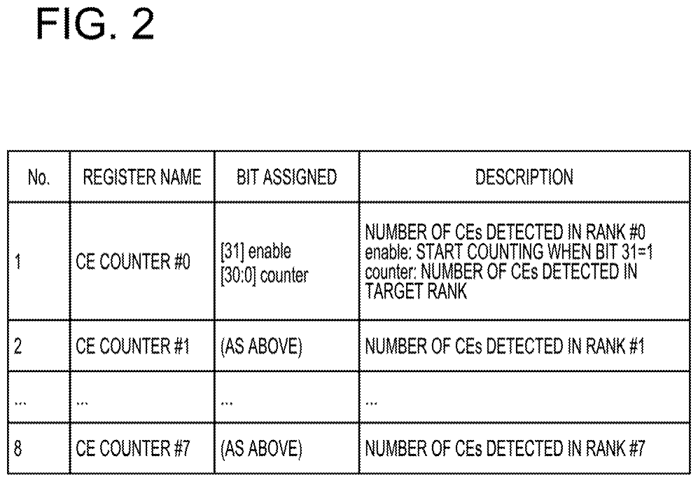

The CE counter 211 counts the number of correctable errors (CEs) of the DIMM 100 connected to the memory controller 210. The unit to count is, for example, a rank 110. FIG. 2 is a diagram illustrating an example of the CE counter 211. As illustrated in FIG. 2, the CE counter 211 has eight (8) registers represented by CE counters #0 to #7. CE counter #0 counts the number of CEs detected in rank #0, CE counter #1 counts the number of CEs detected in rank #1, . . . , and CE counter #7 counts the number of CEs detected in rank #7. The bit length of each register is 32. Bit [31] is an enable bit, which counts CE when bit [31]=1. Bits [30:0] are the number of CEs counted.

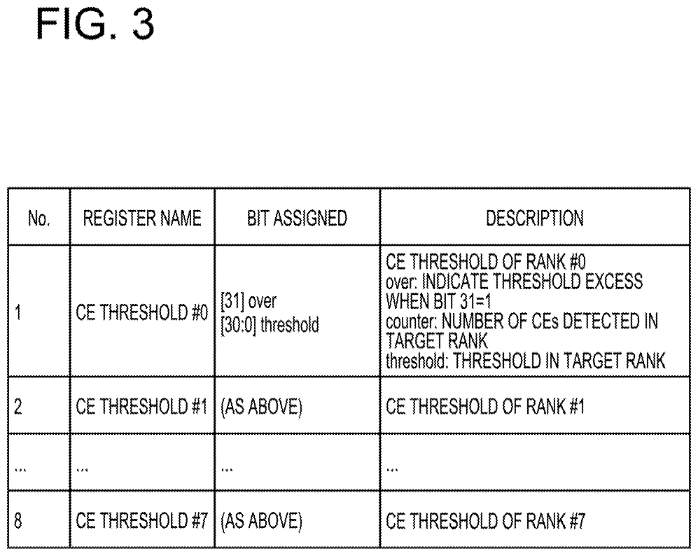

The CE threshold register 212 stores the threshold of CE counted by the CE counter 211 (CE threshold). When the value of the CE counter 211 exceeds the threshold, the memory controller 210 generates an SMI in the CPU 200. FIG. 3 is a diagram illustrating an example of the CE threshold register 212. As illustrated in FIG. 3, the CE threshold register 212 has eight (8) registers represented by CE threshold #0 to CE threshold #7. CE threshold #0 is a register that stores the threshold of the CE of rank #0, CE threshold #1 is a register that stores the threshold of the CE of rank #1, . . . , and CE threshold #7 is a register that stores the threshold of CE of rank #7.

The bit length of each register is 32. Bit [31] is an over bit, and bit [31]=1 indicates that the number of CEs exceeds the threshold. The BIOS 400 may recognize that the threshold excess has occurred in the rank 110 where over bit=1. The over bit is cleared when the BIOS 400 writes “1.” Until the BIOS 400 writes “1” and clears the over bit, the SMI does not occur even when the threshold excess occurs next. Bits [30:0] are the threshold of the target rank 110, and when the bit is 0, the threshold excess is not monitored.

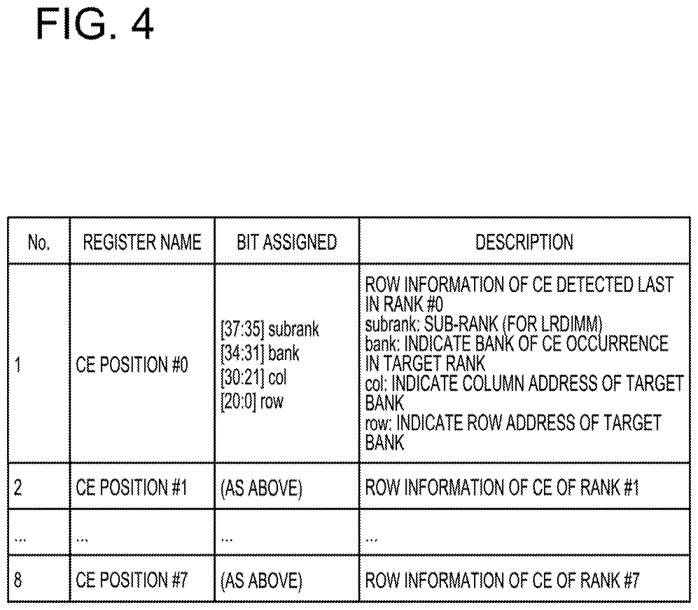

The final CE position register 213 stores the position information of the CE that has occurred last (row address). FIG. 4 is a diagram illustrating an example of the final CE position register 213. As illustrated in FIG. 4, the final CE position register 213 has eight (8) registers represented by CE position #0 to CE position #7. CE position #0 indicates the position information of rank #0, CE position #1 indicates the position information of rank #1, . . . , and CE position #7 indicates the position information of rank #7. The bit length of each register is 38.

Bits [37:35] indicate sub-ranks when the rank 110 has sub-ranks. Bits [34:31] indicate the bank 111 where the CE has occurred last. Bits [30:21] indicate the column address of the CE that has occurred last in the bank 111 where the CE occurs last. Bits [20:0] indicate the row address of the CE that has occurred last in the bank 111 where the CE occurs last.

The power monitoring unit 214 monitors the energy consumption of the DIMM 100 connected to the memory controller 210 and stores the energy consumption in a register. For example, the power monitoring unit 214 includes a counter register that integrates the energy consumption of the DIMM 100 in the unit of 10 micro joules. The BIOS 400 reads the value of the register at the start of measurement and at the end of measurement to calculate the energy consumption per time of the DIMM 100.

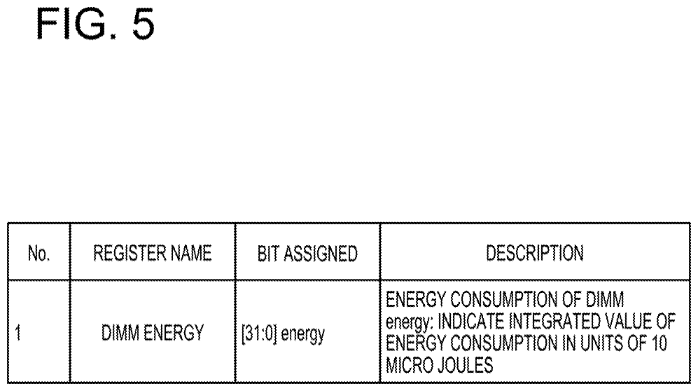

FIG. 5 is a diagram illustrating an example of a register that stores the energy consumption of the DIMM 100. As illustrated in FIG. 5, the register that stores the energy consumption of the DIMM 100 is a 32-bit register, and stores the integrated value of the energy consumption in the unit of 10 micro joules. When there are a plurality of DIMMs 100 connected to the memory controller 210, there are also a plurality of registers.

The temperature monitoring unit 215 monitors the temperature of the DIMM 100 connected to the memory controller 210 and stores the temperature in a register. For example, the temperature monitoring unit 215 includes a register that indicates the temperature of the DIMM 100 in ° C. The BIOS 400 obtains the temperature of the DIMM 100 by reading the register. The BIOS 400 may calculate the average temperature in the measurement section, for example, by reading the register 10 times every 30 seconds from the start of the temperature measurement and taking the average.

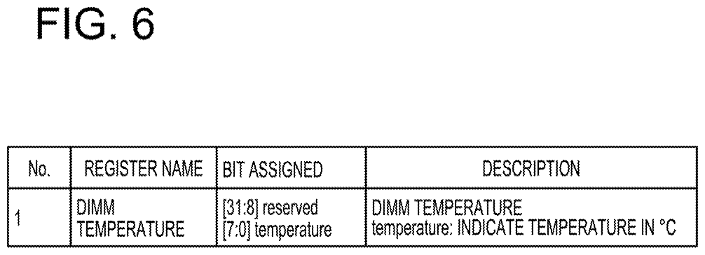

FIG. 6 is a diagram illustrating an example of a register that stores the temperature of the DIMM 100. As illustrated in FIG. 6, the register that stores the temperature of the DIMM 100 is a 32-bit register, and stores the temperature in ° C. using lower 8 bits. The term “reserved” is for future expansion.

The row access monitoring unit 216 monitors access to a specific row 112 of a specific bank 111 in the rank of the DIMM 100 connected to the memory controller 210, and stores the number of accesses in a register. The BIOS 400 designates a row 112 to monitor. For example, the row access monitoring unit 216 includes a register in which the positions of the DIMM 100, the rank 110, the bank 111, and the row 112 are designated by the BIOS 400, and a counter register that integrates the number of accesses to the designated row 112. The BIOS 400 reads the value of the counter register at the start of measurement and at the end of measurement to calculate the number of accesses. The row access monitor unit 216 monitors one row 112 per rank 110 because it is difficult to monitor all the rows due to the large number of rows.

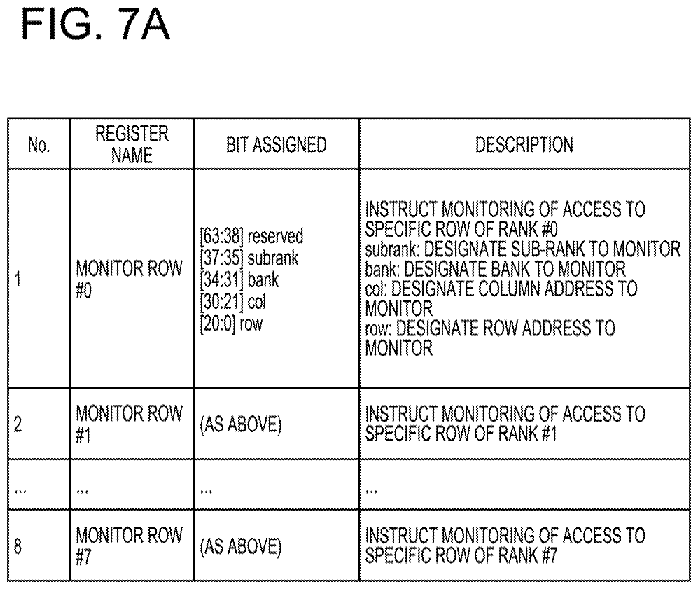

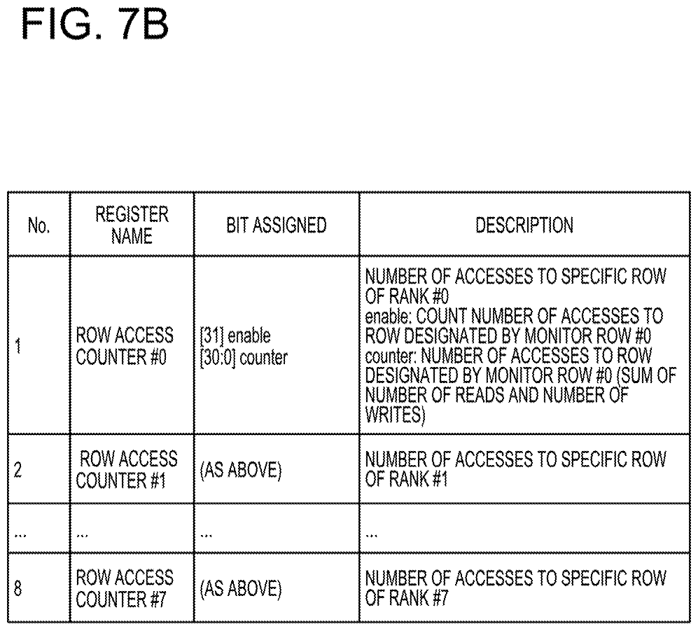

FIG. 7A is a diagram illustrating an example of a register that designates a position at which an access status is monitored, and FIG. 7B is a diagram illustrating an example of a counter register that integrates the number of accesses. As illustrated in FIG. 7A, the register that designates the monitoring position has eight (8) registers represented by monitor row #0 to monitor row #7. Monitor row #0 is a register that designates a monitoring position of rank #0, monitor row #1 is a register that designates a monitoring position of rank #1, . . . , and monitor row #7 is a register that designates a monitoring position of rank #7. The bit length of each register is 64.

When the rank 110 has a sub-rank, bits [37:35] designate the sub-rank to monitor. Bits [34:31] designate the bank 111 to monitor. Bits [30:21] designate a column address to monitor in the monitoring target bank 111. Bits [20:0] designate a row address to monitor in the monitoring target bank 111.

As illustrated in FIG. 7B, the counter register that integrates the number of accesses has eight (8) registers represented by row access counter #0 to row access counter #7. Row access counter #0 is a register that counts the number of accesses of the row 112 designated by monitor row #0, and row access counter #1 is a register that counts the number of accesses of the row 112 designated by monitor row #1. Similarly, the row access counter #7 is a register that counts the number of accesses of the row 112 designated by the monitor row #7. The bit length of each register is 32. Bit [31] is an enable bit, which counts accesses to the row 112 when bit [31]=1. Bits [30:0] are the number of accesses counted. The number of accesses is the sum of the number of reads and the number of writes.

The row access monitoring unit 216 is used to check the usage status of the row 112 for which the sPPR has been performed in an effect confirmation phase (to be described later). The power monitoring unit 214 and the temperature monitoring unit 215 are used to check the usage status of the DIMM 100 for which the sPPR has been performed. The row access monitoring unit 216, the power monitoring unit 214, and the temperature monitoring unit 215 may be used in combination.

Referring back to FIG. 1, the chipset 300 is a combination of an input/output device (IO) in one chip. The chipset 300 may be incorporated in the CPU 200. The chipset 300 is connected to the CPU 200 and the BMC 600. The chipset 300 has a general purpose input/output (GPIO) 310 and an SMI instruction unit 320.

The GPIO 310 is used when the BMC 600 generates an SMI. The SMI instruction unit 320 causes the CPU 200 to generate an SMI.

The BIOS 400 is firmware that is executed when the CPU 200 is started, and performs a process to make elements constituting the information processing apparatus 1, such as the CPU 200 and the DIMM 100, operable. The BIOS 400 has a PPR setting unit 410 and an SMI handler 420.

The PPR setting unit 410 is executed when the BIOS is started, and applies the sPPR and the hPPR. The PPR setting unit 410 has a PPR switching unit 411. The PPR switching unit 411 acquires sPPR position information 621 from the BMC 600 to set sPPR, and acquires hPPR position information 631 from the BMC 600 to set hPPR. When the sPPR is applied, the PPR switching unit 411 notifies the BMC 600 of an application of the sPPR, and when the hPPR is applied, the PPR switching unit 411 notifies the BMC 600 of an application of the hPPR. The BIOS 400 communicates with the BMC 600 using, for example, an intelligent platform management interface (IPMI).

The SMI handler 420 is a handler that operates in response to the SMI from the CPU 200. The SMI handler 420 includes a CE threshold excess processing unit 421, a row position determination unit 422, a CE information collection unit 423, an sPPR effect information collection unit 424, and an IPMI communication unit 425.

The CE threshold excess processing unit 421 determines that the cause of the SMI is a CE threshold excess and calls the row position determination unit 422 to notify the PPR position information to the BMC 600, and then calls the CE information collection unit 423 to start the execution of the information collection phase. The information collection phase is a process of collecting information to specify the row 112 to which the sPPR is applied.

The row position determination unit 422 reads the final CE position register 213 of the memory controller 210, acquires the row position information of the CE that occurs last, creates PPR position information based on the acquired row position information, and notifies such information to the BMC 600.

The CE information collection unit 423 calls the row position determination unit 422 every time the number of CEs exceeds the threshold in the information collection phase, causes the row position information of the CE that occurs last to be acquired, and causes PPR position information to be created based on the acquired row position information, and notifies such information to BMC 600. The BMC 600 aggregates PPR position information and specifies a row position to which the sPPR is applied.

The CE information collection unit 423 changes the CE threshold of the memory controller 210 to a value for information collection smaller than the normal value (e.g., a value of 1/10) at the start of execution of the information collection phase. Further, the CE information collection unit 423 stores the time when the CE threshold is changed, and calculates the time from when the CE threshold is changed to when the CE threshold is next exceeded when the number of CEs exceeds the threshold next time. Then, the CE information collection unit 423 increases (e.g., doubles) the CE threshold when the time from when the CE threshold is changed to when the CE threshold is next exceeded is shorter than a predetermined time. The reason is to avoid being considered as an OS hang.

In the effect confirmation phase, the sPPR effect information collection unit 424 notifies the BMC 600 of DIMM use information which is information indicating the usage status of the DIMM 100. The effect confirmation phase is a process of confirming the effect of the applied sPPR, and the confirmation of the effect is performed based on the usage status of the DIMM 100. The DIMM use information is collected by the power monitoring unit 214, the temperature monitoring unit 215, and the row access monitoring unit 216. The IPMI communication unit 425 communicates with the BMC 600 using an IPMI.

The OS 500 manages the resources such as the DIMM 100 and the CPU 200, and controls the information processing apparatus 1. The OS 500 has a hang monitoring unit 510.

The hang monitoring unit 510 monitors a hang of the OS 500 using a function of causing an interruption to the CPU 200 periodically. Since this function may not operate while the SMI handler 420 is operating, an OS hang is detected by this function when returning from an extended period of process by the SMI handler 420. Similarly, when the process of the SMI handler 420 occurs continuously in a short period time even for a short time, and when the integration of the CPU use time of the SMI handler 420 becomes long, it is considered as an OS hang.

Further, the BIOS 400 and the OS 500 are programs stored in the DIMM 100, read from the DIMM 100, and executed by the CPU 200.

The BMC 600 is a device that is incorporated in the information processing apparatus 1 and manages the information processing apparatus 1. The BMC 600 includes a CE information aggregation unit 610, an sPPR effect management unit 620, an hPPR data management unit 630, an IPMI communication unit 640, and a GPIO 650.

The CE information aggregation unit 610 aggregates PPR position information notified from the CE information collection unit 423 in the information collection phase. Then, at the end of the information collection phase, the CE information aggregation unit 610 specifies the PPR position information that is most frequent, and notifies the sPPR effect management unit 620 of the specified PPR position information.

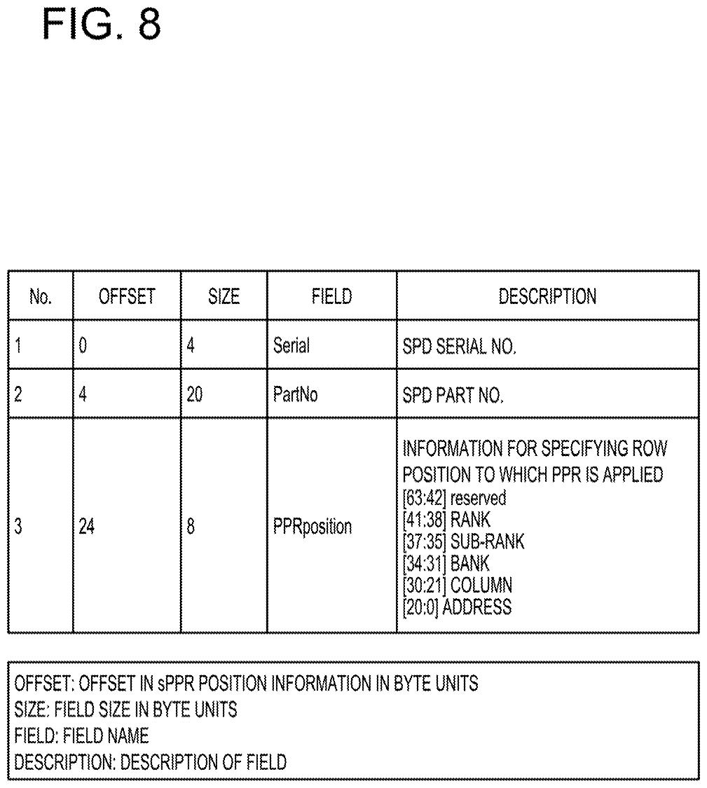

The sPPR effect management unit 620 stores the PPR position information notified from the CE information aggregation unit 610 as sPPR position information 621. The sPPR position information 621 is stored for each rank. FIG. 8 is a diagram illustrating an example of the sPPR position information 621. As illustrated in FIG. 8, the sPPR position information 621 includes 4-byte Serial, 20-byte PartNo, and 8-byte PPRposition.

The term “Serial” refers to an SPD serial number. The term “PartNo” refers to an SPD part number. The DIMM 100 is identified by a serial number and a part number. The term “PPRposition” refers to information that specifies a row position to which the PPR is applied. Bits [20:0] of the “PPRposition” indicate the row 112. Bits [30:21] of the “PPRposition” indicate a column. Bits [34:31] of the “PPR position” indicate the bank 111. Bits [37:35] of the “PPR position” indicate a sub-rank when there is a sub-rank. Bits [41:38] of the “PPR position” indicate the rank 110.

The sPPR effect management unit 620 responds to the sPPR position information 621 based on the request from the PPR switching unit 411. The PPR switching unit 411 applies the sPPR using the sPPR position information 621. The sPPR effect management unit 620 manages information used to confirm the effect of the applied sPPR, and when the effect of the sPPR is confirmed, notifies the sPPR position information 621 to the hPPR data management unit 630.

When notified of PPR position information from the CE information aggregation unit 610, the sPPR effect management unit 620 determines whether there is any PPR position information notified to an sPPR position history 622, and when there is no such information, the sPPR effect management unit 620 adds the notified PPR position information to the sPPR position history 622. The sPPR position history 622 is information indicating the history of the sPPR position information 621. The sPPR position history 622 is stored for each rank.

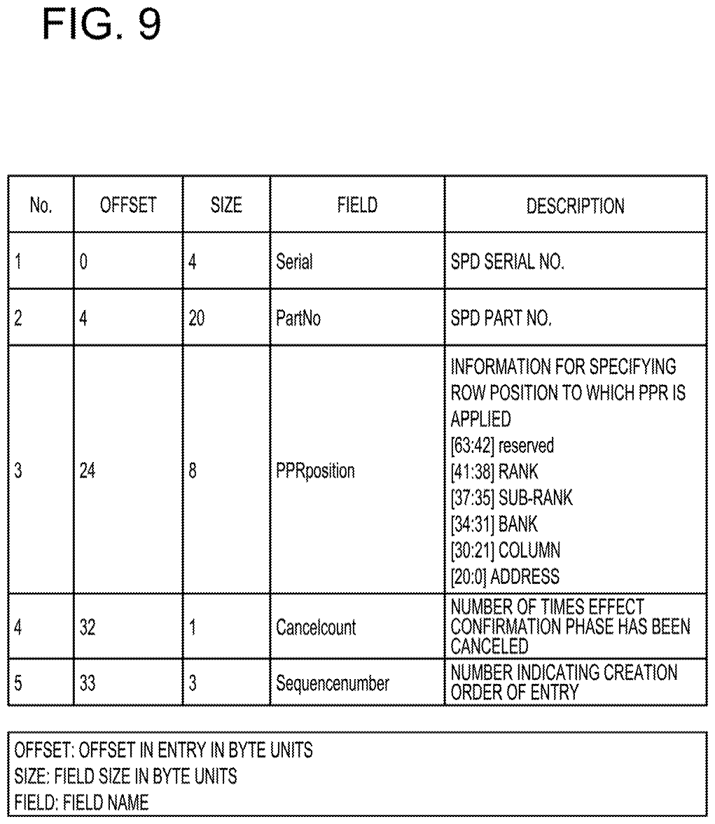

FIG. 9 is a view illustrating an example of the entry of the sPPR position history 622. As illustrated in FIG. 9, the entry of the sPPR position history 622 includes 4-byte Serial, 20-byte PartNo, 8-byte PPRposition, 1-byte Cancelcount, and 3-byte Sequencenumber.

The terms “Serial,” “PartNo,” and “PPRposition” are the same as the information included in the sPPR position information 621. The term “Cancelcount” indicates the number of times the effect confirmation phase has been canceled. The term “Sequencenumber” is a number indicating the creation order of the entry.

The number of entries is, for example, 10. When it is necessary to store the sPPR position history 622 beyond the number of entries to be held, the sPPR effect management unit 620 deletes the one having the smallest Cancelcount, and then stores the sPPR position history 622 beyond the number of entries to be held. At this time, when there is a plurality of pieces of data having the smallest Cancelcount, the sPPR effect management unit 620 deletes the one having the smallest sequence number (oldest one). The term “Sequencenumber” is for recording the creation order of the entries, and when the number overflows, the sPPR effect management unit 620 prevents the overflow by reassigning the number of all the entries from 1.

The sPPR effect management unit 620 determines whether the PPR position information notified from the CE information aggregation unit 610 is in the sPPR position history 622, and when such information exists, the sPPR effect management unit 620 adds 1 to Cancelcount. A case where the PPR position information notified from the CE information aggregation unit 610 is in the sPPR position history 622 refers to a case where the effect confirmation phase has been performed on the PPR position information in the past and a cancellation has been performed halfway.

When Cancelcount exceeds a predetermined threshold, the sPPR effect management unit 620 notifies the hPPR data management unit 630 of the sPPR position information 621 and deletes the same information of the sPPR position information 621 and the sPPR position history 622. This is because the point that the PPR position information having a history of applying the sPPR in the past has been notified from the CE information aggregation unit 610 the number of times the number exceeds the predetermined threshold may be regarded to mean that the position has a high probability of being an hPPR target position.

As described above, when Cancelcount exceeds a predetermined threshold, the sPPR effect management unit 620 may avoid a ping-pong problem by notifying the hPPR data management unit 630 of the sPPR position information.

Here, the ping-pong problem is the following problem. Within a bank, there are two faulty rows 112 that are referred to as row A and row B, respectively. Assuming that the CE occurs with the same degree of frequency, when the sPPR position history 622 is not used, an excess of the CE threshold by row B may be detected during the effect confirmation phase of row A, which may cause the effect confirmation phase of row A to be canceled. Similarly, after that, the effect confirmation phase of row B is performed, but an excess of the CE threshold by row A may be detected halfway, and the effect confirmation phase of row B may be canceled. As described above, when the cancellation of the effect confirmation phase of row A and row B is alternately repeated, there is a possibility that the hPPR may not be applied indefinitely and may not be stable. This problem is a ping-pong problem.

When the effect confirmation phase is intended to apply again to the sPPR position where the Cancelcount exceeds the predetermined threshold by using the sPPR position history 622, the sPPR effect management unit 620 considers that the effect confirmation is completed without passing through the effect confirmation phase, and applies the hPPR. Therefore, the sPPR effect management unit 620 may avoid the ping-pong problem.

Further, when the PPR position information is sent from the row position determination unit 422 in the effect confirmation phase, the CE information aggregation unit 610 requests that the sPPR effect management unit 620 check the PPR position information. Then, the sPPR effect management unit 620 checks whether the DIMM 100 and the rank 110 of the sent PPR position information are the same as the DIMM 100 and the rank 110 of the sPPR position information 621, respectively.

In addition, in the case where the DIMM 100 and the rank 110 of the sent PPR position information are the same as the DIMM 100 and the rank 110 of the sPPR position information 621, respectively, the sPPR effect management unit 620 cancels the effect confirmation phase regarding the rank 110, and stores the PPR position information in the sPPR position history 622.

The reason is that, although the sPPR is applied, since the CE frequently occurs in another row 112 of the same rank 110, the sPPR effect management unit 620 determines that the sPPR has not been effective. When the same PPR position information already exists in the sPPR position history 622, the sPPR effect management unit 620 increments Cancelcount of the PPR position information by one.

The sPPR effect management unit 620 includes an effect measurement time management unit 623 and an effect information aggregation unit 624. The effect measurement time management unit 623 measures the time for effect confirmation, and determines whether an appropriate time has elapsed for the determination of the effect of the sPPR. The effect measurement time management unit 623 holds, for each rank, the start time and the estimated end time using, for example, 64 bits.

The effect measurement time management unit 623 causes the CPU 200 to generate an SMI periodically using the GPIO 650 within a period of the effect confirmation phase, and causes the sPPR effect information collection unit 424 to collect DIMM use information. When the information of the power monitoring unit 214 or the row access monitoring unit 216 is used as DIMM use information used for effect measurement, the effect measurement time management unit 623 generates an SMI once at the beginning and at the end of measurement, respectively. When using the information of the temperature monitoring unit 215 as the DIMM use information, the effect measurement time management unit 623 generates an SMI once at the beginning of measurement, and then periodically (e.g., every 30 seconds) generates the SMI. When the plurality of ranks 110 are to be measured, and when the measurement period is the same, the effect measurement time management unit 623 may generate the SMI by grouping the plurality of ranks 110 together. The effect measurement time is, for example, 60 minutes.

The effect information aggregation unit 624 receives the DIMM use information from the sPPR effect information collection unit 424 and aggregates such information. When using the information of the power monitoring unit 214 or the row access monitoring unit 216 as the DIMM use information, the effect information aggregation unit 624 holds the first DIMM use information and the last DIMM use information notified from the sPPR effect information collection unit 424, for each rank to be measured.

When using the information of the temperature monitoring unit 215 as the DIMM use information, the effect information aggregation unit 624 holds the latest 10 pieces of measurement information notified from the sPPR effect information collection unit 424 for each rank. Then, the effect information aggregation unit 624 calculates the average temperature in a stage where the 10 pieces are aligned, and maintains the temperature as the maximum average temperature. Every time the eleventh and subsequent pieces of information are notified, the effect information aggregation unit 624 deletes one old data, and calculates the average temperature with the latest 10 pieces. When the calculated average temperature exceeds the maximum average temperature, the effect information aggregation unit 624 maintains the value as the maximum average temperature.

When the effect measurement time management unit 623 determines that the time appropriate for determining the effect of the sPPR has passed, the sPPR effect management unit 620 determines whether the DIMM 100 to which the sPPR is applied has been sufficiently used, based on the aggregation result of the DIMM use information. When it is determined that the DIMM 100 to which the sPPR is applied has been sufficiently used, the sPPR effect management unit 620 determines that the sPPR is effective so as to notify the sPPR position information 621 to the hPPR data management unit 630 and delete the sPPR position information 621.

When the information processing apparatus 1 is reset before the effect measurement time management unit 623 determines that the appropriate time has elapsed, or when the power is turned off, the effect measurement time management unit 623 continuously measures the effect confirmation time when the power is turned on next.

The reason for determining whether the DIMM 100 has been sufficiently used is that the CE is not generated when there is no access to the effect confirmation target row 112, and the effect of the sPPR may not be determined when there is no access to the row 112 even after a long time has elapsed. The sPPR effect management unit 620 determines whether the effect confirmation target row 112 has been accessed sufficiently based on the number of accesses monitored by the row access monitoring unit 216.

Further, the sPPR effect management unit 620 uses the power consumption and temperature information of the DIMM 100 to indirectly determine whether the effect confirmation target row 112 has been accessed. The reason is that when the access to the DIMM 100 occurs for a sufficiently long period of time, it may be expected that there is also an access to the effect confirmation target row 112. For example, when it is necessary to make a determination beyond the number of rows 112 that may be monitored by the row access monitoring unit 216, the sPPR effect management unit 620 also uses an indirect determination.

In the case of using the number of accesses measured by the row access monitoring unit 216, for example, when the number of accesses per hour to the effect confirmation target row 112 exceeds a predetermined threshold access number, the sPPR effect management unit 620 determines that there have been sufficient accesses.

In the case of using the energy consumption measured by the power monitoring unit 214, for example, when the energy consumption per time consumed by the effect confirmation target DIMM 100 exceeds a predetermined threshold energy amount, the sPPR effect management unit 620 determines that there have been sufficient accesses.

When the temperature measured by the temperature monitoring unit 215 is used, for example, when the maximum average temperature of the effect confirmation target DIMM 100 exceeds a predetermined threshold temperature after the end of the effect measurement period, the sPPR effect management unit 620 determines that there have been sufficient accesses. The threshold differs depending on the type of the DIMM 100 and the like, and therefore, is determined in advance by a test.

The hPPR data management unit 630 manages, for each rank, hPPR position information 631 which is PPR position information for applying the hPPR. The hPPR data management unit 630 stores the PPR position information notified from the sPPR effect management unit 620 as the hPPR position information 631. The hPPR data management unit 630 responds to the hPPR position information 631 based on the request from the PPR switching unit 411. When notified of the application of the hPPR by the PPR switching unit 411, the hPPR data management unit 630 deletes the hPPR position information 631.

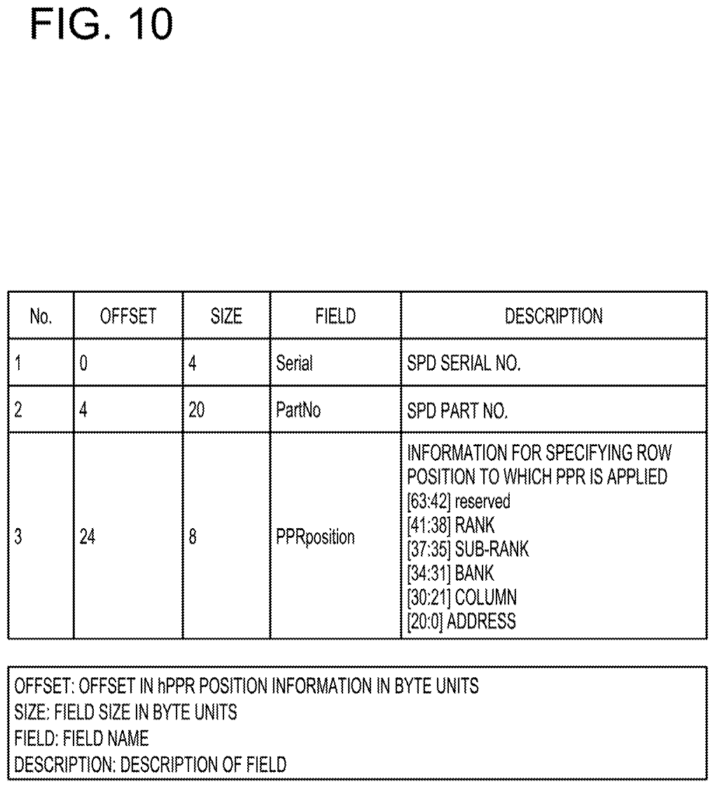

FIG. 10 is a diagram illustrating an example of the hPPR position information 631. As illustrated in FIG. 10, the hPPR position information 631 includes 4-byte Serial, 20-byte PartNo, and 8-byte PPRposition. The terms “Serial,” “PartNo,” and “PPRposition” are the same as the information included in the sPPR position information 621.

When the hPPR position information 631 includes information related to the DIMM 100 that does not exist in the information processing apparatus 1, the hPPR data management unit 630 deletes the hPPR position information 631. The reason is that it is assumed that the DIMM 100 corresponding to the hPPR position information 631 has been replaced.

The IPMI communication unit 640 communicates with the IPMI communication unit 425 using an IPMI. In particular, when communicating with the BIOS 400 or the OS 500, a keyboard controller style (KCS) interface or the like is used.

The GPIO 650 is connected to the GPIO 310 of the chipset 300. The BMC 600 may generate an SMI in the SMI instruction unit 320 of the chipset 300 by operating the GPIO 650.

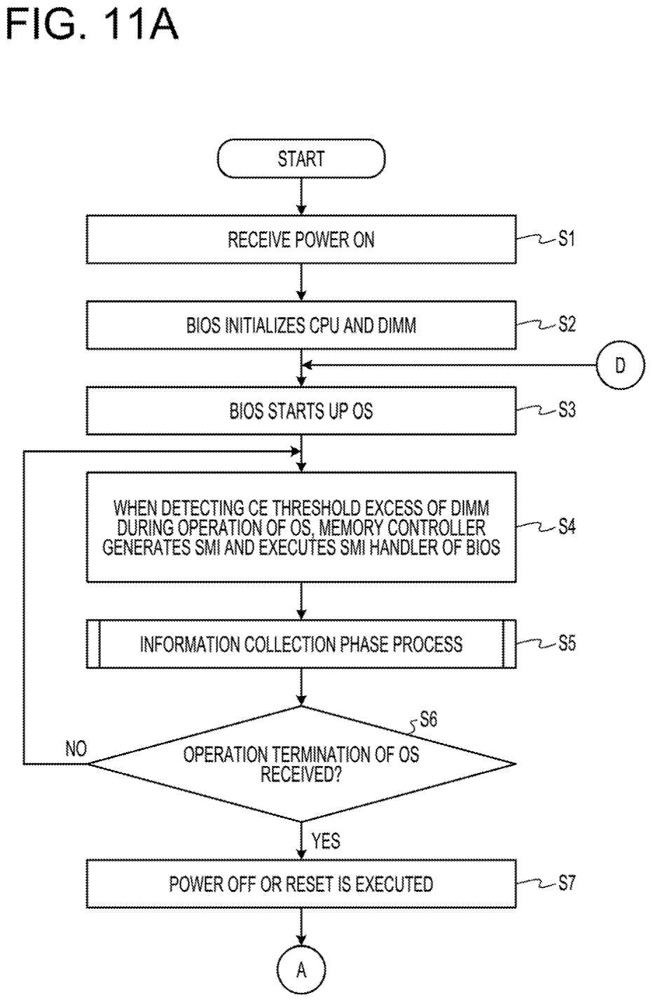

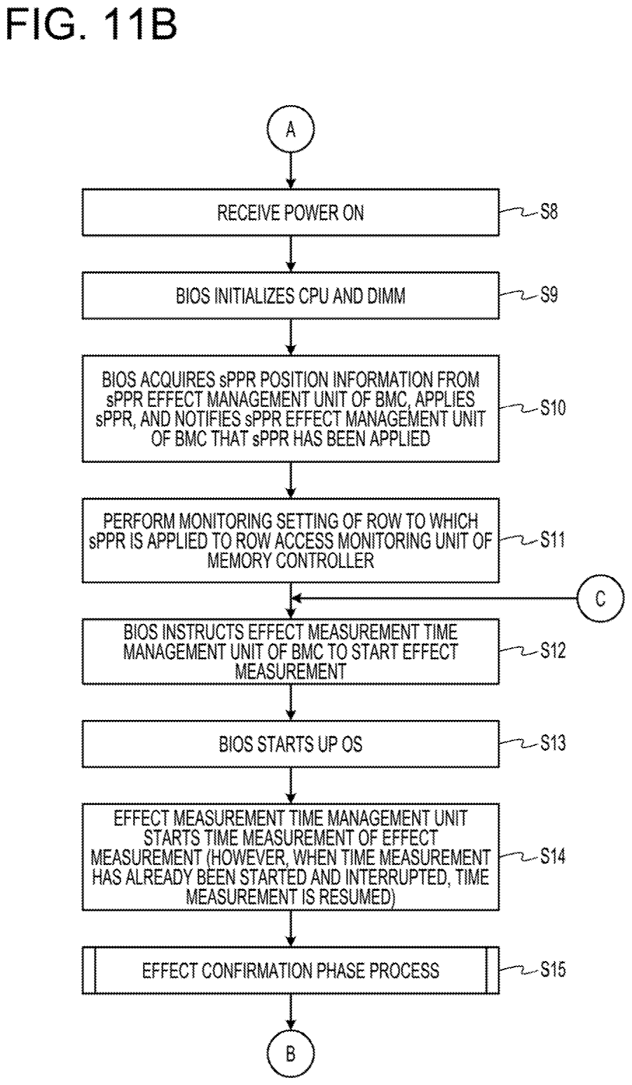

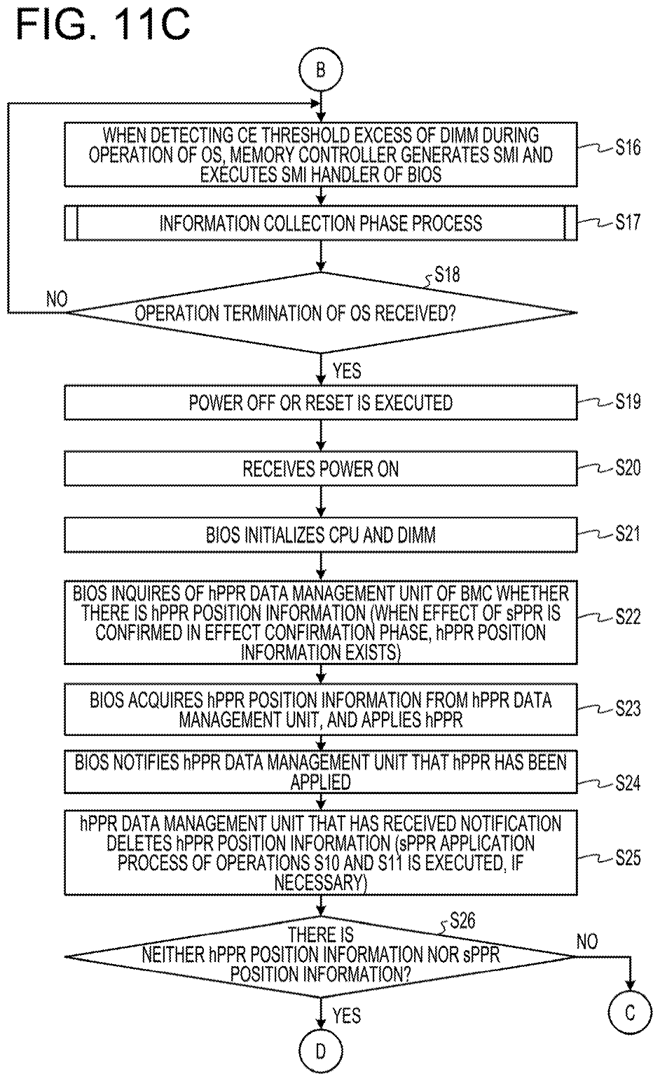

Next, the flow of a PPR process by the information processing apparatus 1 will be described. FIGS. 11A to 11C are flowcharts each illustrating the flow of the PPR process by the information processing apparatus 1. As illustrated in FIG. 11A, the information processing apparatus 1 receives a power on (operation S1). Then, the BIOS 400 initializes the CPU 200 and the DIMM 100 (operation S2). Initially, it is assumed that neither the sPPR position information 621 nor the hPPR position information 631 is present.

Then, the BIOS 400 starts up the OS 500 (operation S3). Also, when the memory controller 210 detects that the CE threshold of the DIMM 100 is exceeded during operation of the OS 500, the memory controller 210 generates an SMI and executes the SMI handler 420 of the BIOS 400 (operation S4). Then, the information processing apparatus 1 executes an information collection phase process (operation S5).

Then, the information processing apparatus 1 determines whether the operation termination of the OS 500 has been received (operation S6).

When it is determined that the operation termination has not been received, the process returns to operation S4, and when it is determined that the operation termination has been received, power off or reset is executed (operation S7).

After that, when a power off is received, as illustrated in FIG. 11B, the information processing apparatus 1 receives the power on (operation S8).

Then, the BIOS 400 initializes the CPU 200 and the DIMM 100 (operation S9). At this time, the BIOS 400 acquires the sPPR position information 621 from the sPPR effect management unit 620 of the BMC 600, applies the sPPR, and notifies the sPPR effect management unit 620 that the sPPR has been applied (operation S10). Then, the BIOS 400 performs a monitoring setting of the row 112 to which the sPPR is applied to the row access monitoring unit 216 of the memory controller 210 (operation S11).

Further, the BIOS 400 instructs the effect measurement time management unit 623 of the BMC 600 to start the effect measurement (operation S12), and starts up the OS 500 (operation S13). Then, the effect measurement time management unit 623 starts time measurement of the effect measurement (operation S14). Here, the effect confirmation phase is started. However, since the power of the information processing apparatus 1 is turned off and turned on during the effect measurement, when the time measurement has already been started and interrupted, the effect measurement time management unit 623 resumes the time measurement. Then, the information processing apparatus 1 executes the effect confirmation phase process (operation S15).

Further, as illustrated in FIG. 11C, when the memory controller 210 detects that the CE threshold of the DIMM 100 is exceeded during operation of the OS 500, the memory controller 210 generates an SMI and executes the SMI handler 420 of the BIOS 400 (operation S16). Then, the information processing apparatus 1 executes the information collection phase process (operation S17).

The process of operation S16 and operation S17 is a process in the case where a CE threshold excess is detected in a rank 110 different from the rank 110 which is the effect confirmation target. Even when there is a rank 110 that is a target of the effect confirmation phase, and when the CE threshold excess occurs in the rank 110 that is not the target of the effect confirmation phase, the information processing apparatus 1 performs the information collection phase for the rank 110.

Then, the information processing apparatus 1 determines whether the operation termination of the OS 500 has been received (operation S18). When it is determined that the operation termination has not been received, the process returns to operation S16, and when it is determined that the operation termination has been received, power off or reset is executed (operation S19).

Thereafter, when the power off is received, the information processing apparatus 1 receives the power on (operation S20). Then, the BIOS 400 initializes the CPU 200 and the DIMM 100 (operation S21). At this time, the BIOS 400 inquires of the hPPR data management unit 630 of the BMC 600 whether there is the hPPR position information 631 (operation S22). When the effect of the sPPR is confirmed in the effect confirmation phase, the hPPR position information 631 exists.

When the hPPR position information 631 exists, the BIOS 400 acquires the hPPR position information 631 from the hPPR data management unit 630, and applies the hPPR (operation S23). Then, the BIOS 400 notifies the hPPR data management unit 630 that the hPPR has been applied (operation S24). The hPPR data management unit 630 that has received the notification deletes the hPPR position information 631 (operation S25). Also, the BIOS 400 executes the sPPR application process of operation S10 and operation S11, if necessary.

Then, the BIOS 400 determines whether there is neither hPPR position information 631 nor sPPR position information 621 (operation S26). When neither exists, the process returns to operation S3, and when at least one exists, the process returns to operation S12.

Thus, the information processing apparatus 1 specifies the row 112 to which the sPPR is applied in the information collection phase, applies the sPPR to the specified row 112, confirms the effect of the sPPR in the effect confirmation phase, and applies the hPPR when confirming the effect of the sPPR. Therefore, the information processing apparatus 1 may appropriately specify and repair the row 112 in which the CE occurs.

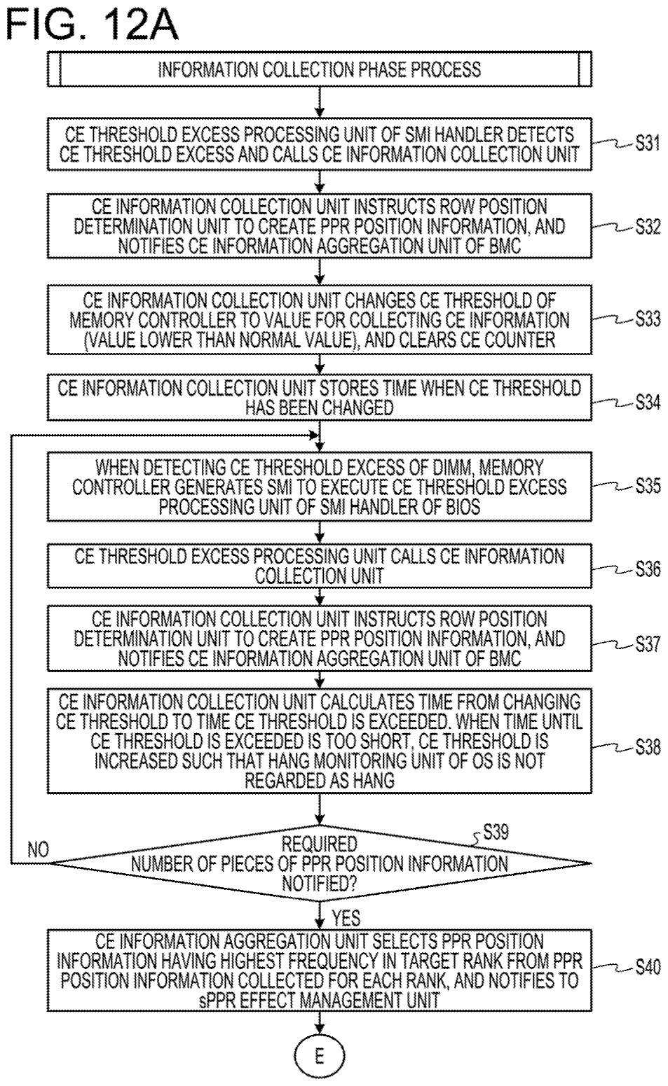

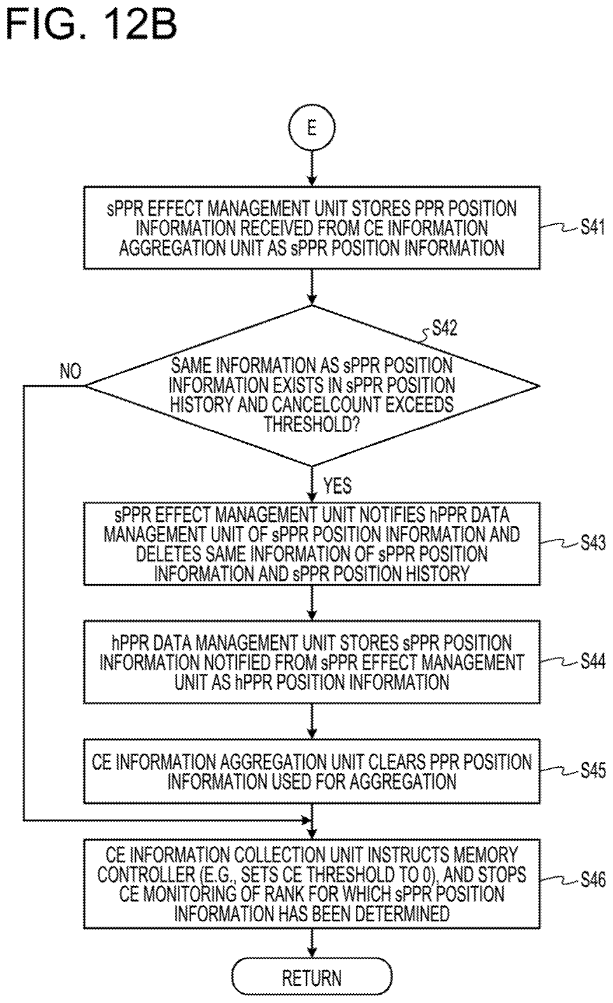

FIGS. 12A and 12B are flowcharts illustrating the flow of the information collection phase process. As illustrated in FIG. 12A, the CE threshold excess processing unit 421 of the SMI handler 420 detects a CE threshold excess and calls the CE information collection unit 423 (operation S31).

The CE information collection unit 423 instructs the row position determination unit 422 to create PPR position information, and notifies the CE information aggregation unit 610 of the BMC 600 (operation S32). Then, the CE information collection unit 423 changes the CE threshold of the memory controller 210 to a value for collecting CE information (a value lower than the normal value), and clears the CE counter 211 (operation S33). By changing the CE threshold to a lower value, the CE information collection unit 423 may accelerate the CE threshold excess, and may accelerate the specification of the sPPR position information 621 by the CE information aggregation unit 610. Then, the CE information collection unit 423 stores the time when the CE threshold has been changed (operation S34).

Then, when the CE threshold excess of the DIMM 100 is detected, the memory controller 210 generates an SMI to execute the CE threshold excess processing unit 421 of the SMI handler 420 of the BIOS 400 (operation S35).

Further, the CE threshold excess processing unit 421 calls the CE information collection unit 423 (operation S36). Then, the CE information collection unit 423 instructs the row position determination unit 422 to create PPR position information, and notifies the CE information aggregation unit 610 of the BMC 600 (operation S37). Then, the CE information collection unit 423 calculates the time from changing the CE threshold to the time the CE threshold is exceeded. When the time until the CE threshold is exceeded is too short, the CE threshold is increased such that the hang monitoring unit 510 of the OS 500 is not regarded as a hang (operation S38).

Then, the CE information collection unit 423 determines whether the required number of pieces of PPR position information has been notified to the BMC 600 (operation S39), and when it is determined that such a number has not been notified, the process returns to operation S35. Meanwhile, when it is determined that the required number of pieces of PPR position information has been notified to the BMC 600, the CE information aggregation unit 610 selects the PPR position information having the highest frequency in the target rank from the PPR position information collected for each rank, and notifies such information to the sPPR effect management unit 620 (operation S40).

Further, as illustrated in FIG. 12B, the sPPR effect management unit 620 stores the PPR position information received from the CE information aggregation unit 610 as the sPPR position information 621 (operation S41). Then, the sPPR effect management unit 620 determines whether the same information as the sPPR position information 621 exists in the sPPR position history 622 and whether Cancelcount exceeds the threshold (operation S42). Then, when it is determined that the same information as the sPPR position information 621 does not exist in the sPPR position history 622 or the Cancelcount does not exceed the threshold, the sPPR effect management unit 620 proceeds to operation S46.

In the meantime, when the determination result of operation S42 is “Yes,” the sPPR effect management unit 620 notifies the hPPR data management unit 630 of the sPPR position information 621 and deletes the same information of the sPPR position information 621 and the sPPR position history 622 (operation S43). Then, the hPPR data management unit 630 stores the sPPR position information 621 notified from the sPPR effect management unit 620 as the hPPR position information 631 (operation S44).

In the information collection phase, when the determination result of operation S42 is “Yes,” the information processing apparatus 1 may alleviate the ping-pong problem by setting the sPPR position information 621 to the hPPR position information 631. The reason is that the determination result of operation S42 being “Yes” indicates that the CE threshold excess has occurred at a high frequency in the past, and the reliability of the sPPR position information 621 is high.

Further, the CE information aggregation unit 610 clears the PPR position information used for the aggregation (operation S45). Then, the CE information collection unit 423 instructs the memory controller 210 (e.g., sets the CE threshold to 0), and stops CE monitoring of the rank 110 for which the sPPR position information 621 has been determined (operation S46).

As described above, since the CE information aggregation unit 610 selects the PPR position information having the highest frequency in the target rank from the PPR position information collected for each rank, and notifies the selected information to the sPPR effect management unit 620, the accuracy of the sPPR position information 621 may be improved.

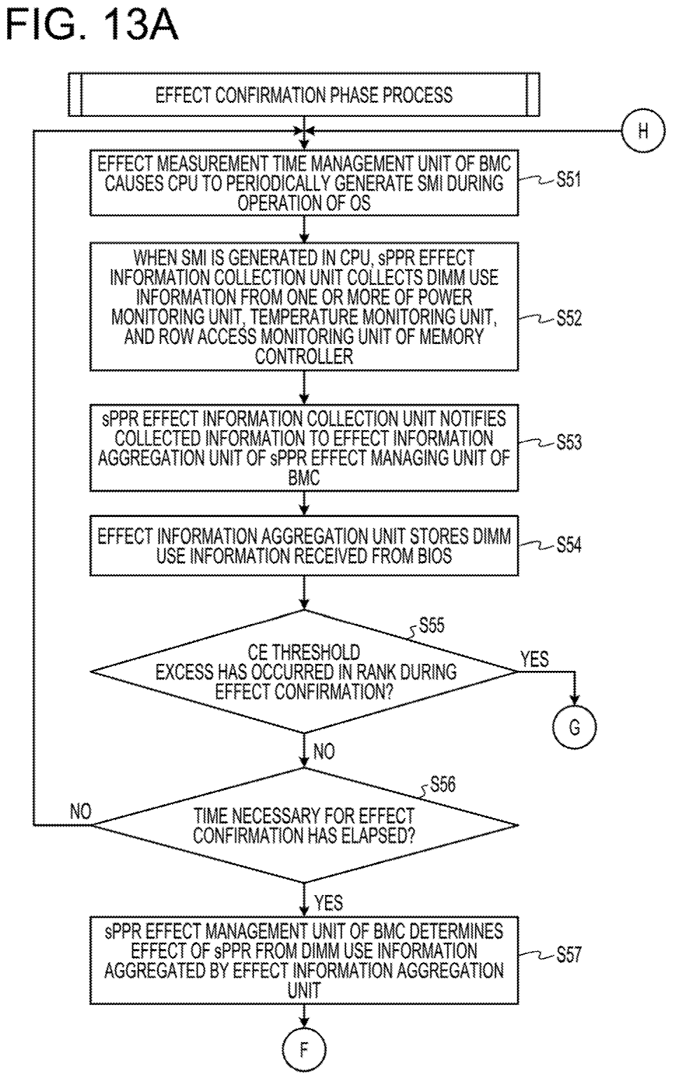

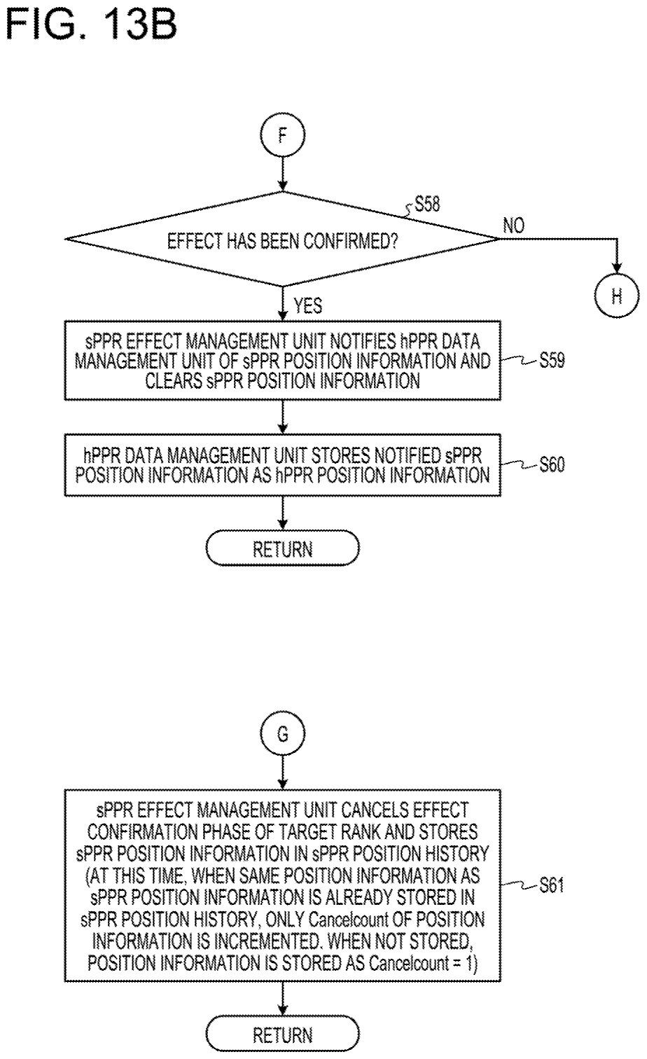

FIGS. 13A and 136 are flowcharts each illustrating the flow of the effect confirmation phase process. As illustrated in FIG. 13A, the effect measurement time management unit 623 of the BMC 600 causes the CPU 200 to periodically generate an SMI during operation of the OS 500 (operation S51). In the effect confirmation phase, the effect measurement time management unit 623 generates an SMI at a constant time interval within the effect confirmation period in order to confirm the effects in a predetermined period. The SMI is generated because the BIOS 400 collects DIMM use information for effect measurement, but there is an SMI as a method of operating the BIOS 400 during to the OS operation.

Further, the reason for generating the SMI at constant intervals is as follows. When using temperature information of the temperature monitoring unit 215 as DIMM use information, the sPPR effect management unit 620 adopts an average temperature within a predetermined time. Since the temperature that the BIOS 400 may collect in one SMI is the temperature at that time, multiple pieces of temperature information are required to take an average. For this reason, the effect measurement time management unit 623 generates the SMI at constant intervals to collect information. In addition, when the integrated power amount information of the power monitoring unit 214 or the integrated access number of the row access monitoring unit 216 is used as the DIMM use information, the SMI may be generated only at the beginning and at the end of the effect confirmation phase.

Further, when the SMI is generated in the CPU 200, the sPPR effect information collection unit 424 collects DIMM use information from one or more of the power monitoring unit 214, the temperature monitoring unit 215, and the row access monitoring unit 216 of the memory controller 210 (operation S52). Then, the sPPR effect information collection unit 424 notifies the collected information to the effect information aggregation unit 624 of the sPPR effect management unit 620 of the BMC 600 (operation S53).

Further, the effect information aggregation unit 624 stores the DIMM use information received from the BIOS 400 (operation S54). Then, the sPPR effect management unit 620 determines whether the CE threshold excess has occurred in the rank 110 during the effect confirmation (operation S55), and when it is determined that such an excess occurs, the process proceeds to operation S61.

In the meantime, when the CE threshold excess is not occurring in the rank 110 during effect confirmation, the effect measurement time management unit 623 determines whether the time necessary for effect confirmation has elapsed (operation S56), and when it is determined that the time has not elapsed, the process returns to operation S51. Meanwhile, when it is determined that the time necessary for effect confirmation has elapsed, the sPPR effect management unit 620 of the BMC 600 determines the effect of sPPR from the DIMM use information aggregated by the effect information aggregation unit 624 (operation S57).

At this time, since there is no occurrence of the CE threshold excess in the effect confirmation target rank 110, when sufficient accesses from the memory controller 210 to the sPPR target row 112 occur in the effect confirmation period, the sPPR effect management unit 620 may determine that there is an sPPR effect.

Further, the sPPR effect management unit 620 determines whether the effect may be confirmed (operation 558), and when it is determined that the effect has not been confirmed, the process returns to operation S51. The case where the effect may not be confirmed refers to a case where it may not be determined that accesses to the effect confirmation target row 112 or the DIMM 100 including the effect confirmation target row 112 have occurred sufficiently. In this case, there is a high possibility that the CE threshold excess has not occurred because there is no access to the effect confirmation target row 112 or the DIMM 100 including the effect confirmation target row 112. Thus, it is not possible to determine that the effect of applying the sPPR may suppress the occurrence of CE. Therefore, the sPPR effect management unit 620 suspends the determination until the access to the effect confirmation target row 112 sufficiently occurs. Here, the sPPR effect management unit 620 extends the effect confirmation period and repeats the effect confirmation phase from operation S51.

Meanwhile, when the effect may be confirmed, the sPPR effect management unit 620 notifies the hPPR data management unit 630 of the sPPR position information 621 and clears the sPPR position information 621 (operation S59). Then, the hPPR data management unit 630 stores the notified sPPR position information 621 as the hPPR position information 631 (operation S60), and ends the process.

Further, when the CE threshold excess occurs in the rank 110 during effect confirmation in operation S55, the sPPR effect management unit 620 cancels the effect confirmation phase of the target rank, 110 and stores the s sPPR position information 621 in the sPPR position history 622 (operation S61).

The reason for canceling the effect confirmation phase is that it may be considered that there is no effect of the sPPR because the CE threshold excess occurs despite the application of the sPPR. However, in order to alleviate the ping-pong problem, the sPPR effect management unit 620 stores the sPPR position information 621 of the effect confirmation target in the sPPR position history 622. The information stored in the sPPR position history 622 relates to the row 112 that is once considered to have a high occurrence frequency of CE.

Further, when the same position information as the sPPR position information 621 is already stored in the sPPR position history 622, the sPPR effect management unit 620 increments only the Cancelcount of the position information. Meanwhile, when such information is not stored, the sPPR effect management unit 620 stores the position information by taking Cancelcount=1.

As described above, the information processing apparatus 1 may apply the hPPR to a row having the sPPR effect at the next startup so that the sPPR effect management unit 620 notifies the hPPR data management unit 630 of the sPPR position information 621 for confirming the effect of the sPPR.

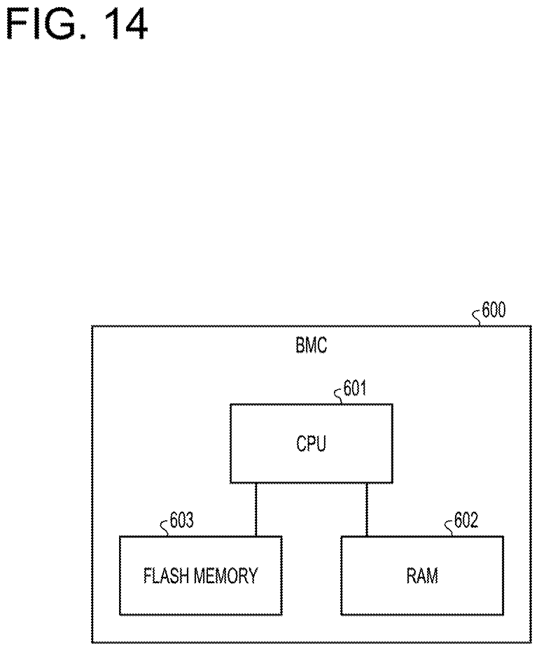

Next, an example of the hardware configuration of the BMC 600 will be described. FIG. 14 is a diagram illustrating an example of a hardware configuration of the BMC 600. As illustrated in FIG. 14, the BMC 600 includes a CPU 601, a RAM 602, and a flash memory 603.

The CPU 601 is a central processing unit that reads a program from the RAM 602 and executes the program. The RAM 602 is a memory that stores a program or an intermediate result of execution of the program. The flash memory 603 is a memory that stores a program and data.

Further, a repair management program executed in the BMC 600 is stored, for example, in a CD-R, which is an example of a recording medium readable by the BMC 600, read from the CD-R, and installed in the BMC 600. Alternatively, the repair management program may be stored in a database or the like of a computer system connected via a local area network (LAN), read from these databases, and installed in the BMC 600. Then, the installed repair management program may be stored in the flash memory 603, read out to the RAM 602, and executed by the CPU 601.

As described above, in the embodiment, when the CE threshold excess occurs, the row position determination unit 422 of the BIOS 400 acquires the row position information of the CE that occurs last, creates PPR position information, and notifies the BMC 600 of the created PPR position information. Then, the CE information aggregation unit 610 of the BMC 600 aggregates the plurality of pieces of PPR position information notified by the row position determination unit 422 to specify the PPR position information having the highest frequency, and notifies the aggregated information to the sPPR effect management unit 620. Then, the sPPR effect management unit 620 stores the notified PPR position information as sPPR position information 621. Then, the PPR switching unit 411 of the BIOS 400 acquires the sPPR position information 621 from the sPPR effect management unit 620 and applies the sPPR. Then, the sPPR effect management unit 620 determines the effect of the sPPR, and when it is determined that there is an effect, notifies the hPPR data management unit 630 of the sPPR position information 621. Then, the hPPR data management unit 630 stores the notified sPPR position information 621 as hPPR position information 631. Therefore, the information processing apparatus 1 may apply the hPPR to an appropriate row 112.

Further, in the embodiment, the information processing apparatus 1 performs the application of the hPPR including the disconnection of a fuse which may not be restored, after confirming the effect of the sPPR. Therefore, wasteful use of the spare row 113 may be suppressed by applying the hPPR to the inappropriate row 112.

Further, in the embodiment, when the sPPR effect management unit 620 is notified of the PPR position information, the CE information aggregation unit 610 deletes the PPR position information used for the aggregation. In addition, when the hPPR data management unit 630 is notified of the sPPR position information 621, the sPPR effect management unit 620 deletes the sPPR position information 621. Therefore, the information processing apparatus 1 may reduce the area required to store the PPR position information.

Further, in the embodiment, when the row position determination unit 422 first acquires the row position information of the CE that occurs last, since the CE information collection unit 423 changes the CE threshold to a smaller value, the time for information collection phase may be shortened.

In addition, in the embodiment, when the row position determination unit 422 secondly acquires the row position information of the CE that occurs last, the CE information collection unit 423 determines whether the elapsed time after changing the CE threshold to a smaller value is smaller than a predetermined threshold. Then, when the value is smaller than the predetermined threshold, the CE information collection unit 423 changes the CE threshold to a larger value. Therefore, it is possible to prevent the hang monitoring unit 510 of the OS 500 from erroneously recognizing the information collection process for PPR as a hang of the OS 500.

Further, in the embodiment, since the sPPR effect management unit 620 determines that the sPPR is effective when the effect measurement time has elapsed and the DIMM use information is larger than the predetermined threshold, it is possible to accurately determine the presence or absence of the sPPR effect.

In addition, in the embodiment, since the sPPR effect management unit 620 determines that the sPPR is effective when the number of accesses to the row 112 to which the sPPR is applied is larger than a predetermined threshold access number, it is possible to accurately determine the presence or absence of the sPPR effect.

In addition, in the embodiment, the sPPR effect management unit 620 determines that the sPPR is effective when the power consumption of the DIMM 100 is larger than the threshold power amount or the average temperature of the DIMM 100 is larger than the threshold temperature. Therefore, the sPPR effect management unit 620 may indirectly determine the presence or absence of the sPPR effect.

Further, in the embodiment, when the CE threshold excess occurs in the same rank 110 while confirming the effect of the sPPR, the sPPR effect management unit 620 determines whether the corresponding sPPR position information 621 is in the sPPR position history 622 and Cancelcount is larger than the threshold. Then, when it is determined that the corresponding sPPR position information 621 is in the sPPR position history 622 and Cancelcount is larger than the threshold, the sPPR effect management unit 620 notifies the hPPR data management unit 630 of the sPPR position information 621. Therefore, the sPPR effect manager 620 may prevent the occurrence of the ping-pong problem.

Further, in the embodiment, although the embodiment has been described for the case where the main memory is the DIMM 100, the main memory may be another semiconductor storage device having a spare area. In addition, in the embodiment, descriptions have been made on a case where the PPR is applied to the row 112, but the information processing apparatus 1 may apply the PPR to another area of the semiconductor storage device.

Further, in the embodiment, descriptions have been made on a case where the position information of the CE that occurs last is used, but the information processing apparatus 1 may use the position information of the CE other than that occurs last. In addition, in the embodiment, descriptions have been made on a case where the PPR position information having the highest frequency is set as sPPR position information 621, but the information processing apparatus 1 may set other PPR position information such as, for example, the PPR position information having the second highest frequency as the sPPR position information 621.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to an illustrating of the superiority and inferiority of the invention. Although the embodiments of the present invention have been described in detail, it should be understood that the various changes, substitutions, and alterations could be made hereto without departing from the spirit and scope of the invention.

What is claimed is:

1. An information processing apparatus comprising:
a memory; and
a processor coupled to the memory and configured to:
acquire position information of regions of the memory where a correctable error occurs when detecting the correctable error over a predetermined number of times having a first value;
to specify, as software repair position information, position information having a frequency higher than the frequency of other position information among the acquired position information of regions;
perform a software repair of a region indicated by the specified software repair position information; and
confirm a presence or absence of an effect of the software repair of the region; and when the effect is determined to be present, set the software repair position information as hardware repair position information.

2. The information processing apparatus according to claim 1,
wherein the processor is further configured to change the predetermined number of times to a second value smaller than the first value when the position information is acquired for a first time.

3. The information processing apparatus according to claim 2,
wherein, when the position information is acquired for a second time, and when an elapsed time from a time when the predetermined number of times is changed to the second value is smaller than a predetermined time, the processor is configured to change the predetermined number of times to a third value larger than the second value.

4. The information processing apparatus according to claim 1,
wherein the processor is configured to determine the effect of the software repair to be present, when the correctable error is not detected for the predetermined number of times in a predetermined period of time for the region where the software repair is performed and a usage amount of the region where the software repair is performed is larger than a predetermined usage amount.

5. The information processing apparatus according to claim 4,
wherein the usage amount and the predetermined usage amount are a number of accesses to the region where the software repair is performed and a predetermined number of accesses to the region where the software repair is performed, respectively.

6. The information processing apparatus according to claim 4,
wherein the usage amount and the predetermined usage amount are a power consumption amount of the memory and a predetermined power consumption amount of the memory, respectively.

7. The information processing apparatus according to claim 4,
wherein the usage amount and the predetermined usage amount are a temperature during the predetermined period of time of the memory and a predetermined temperature during the predetermined period of time of the memory, respectively.

8. The information processing apparatus according to claim 4,
wherein the processor is configured to generate an interruption during the predetermined period of time to cause a basic input/output system (BIOS) to collect the usage amount.

9. The information processing apparatus according to claim 1,
wherein the processor is configured to: when the correctable error is detected for the predetermined number of times in another region while confirming the presence or absence of the effect of the software repair,
cancel to confirm the presence or absence of the effect of the software repair,
increase a value of a counter associated with the software repair position information, and
set the software repair position information as hardware repair position information when the value of the counter exceeds a predetermined value.

10. The information processing apparatus according to claim 2,
wherein the software repair of the region replaces the region with a spare region, the memory is a dual inline memory module (DIMM), the region is a row of the DIMM, and the spare region is a spare row of the DIMM.

11. A computer-readable non-transitory recording medium having stored therein a program that causes a computer to execute a procedure, the procedure comprising:
acquiring position information of regions of the memory where a correctable error occurs when detecting the correctable error over a predetermined number of times having a first value;
specifying, as software repair position information, position information having a frequency higher than the frequency of other position information among the acquired position information of regions;
performing a software repair of a region indicated by the specified software repair position information; and
confirming a presence or absence of an effect of the software repair of the region, and when the effect is determined to be present, set the software repair position information as hardware repair position information.

12. The computer-readable non-transitory recording medium according to claim 11,
wherein the procedure determines the effect of the software repair to be present, when the correctable error is not detected for the predetermined number of times in a predetermined period of time for the region where the software repair is performed and a usage amount of the region where the software repair is performed is larger than a predetermined usage amount.

13. The computer-readable non-transitory recording medium according to claim 11,
wherein, when the correctable error is detected for the predetermined number of times in another region while confirming the presence or absence of the effect of the software repair, the procedure:
cancels to confirm the presence or absence of the effect of the software repair,
increases a value of a counter associated with the software repair position information, and
sets the software repair position information as hardware repair position information when the value of the counter exceeds a predetermined value.
